(19) United States
(12) Patent Application Publication
(10) Pub. No.: US 2024/0105362 A1
(43) Pub. Date: Mar. 28, 2024

(54) COMMUNICATION ELECTRIC WIRE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Yuta YASUYOSHI, Mie (JP); Tatsuya SHIMADA, Mie (JP)

(21) Appl. No.: 18/273,130

(22) PCT Filed: Jan. 6, 2022
(86) PCT No.: PCT/JP2022/000253

§ 371 Date: Jul. 19, 2023

(30) Foreign Application Priority Data
Jan. 20, 2021 (JP) 2021-007369

(51) Int. Cl. H01B 11/18; H05K 9/00

(52) U.S. Cl. CPC H01B 11/1895; H05K 9/0098

(57) ABSTRACT

A communication electric wire 1 includes: a conductor 2; an insulating layer 3 covering an outer periphery of the conductor 2; and a magnetic sheath layer 8 covering an outside of the insulating layer 3, wherein the magnetic sheath layer 8 contains an organic polymer and a magnetic material, the magnetic sheath layer 8 contains 15 parts by mass or more of an acid-modified polymer in 100 parts by mass of the entire organic polymer, and the magnetic material is composed of particles with an average particle diameter of 50 μm or less, and a content of the magnetic material in the magnetic sheath layer 8 is 300 parts by mass or more with respect to 100 parts by mass of the entire organic polymer.

### TECHNICAL FIELD

The present disclosure relates to communication electric wires.

### BACKGROUND

In some communication electric wires (i.e. electric wires for communication) used in fields such as automobiles, a shield layer is provided on the outside of the core wire for the purpose of reducing noise entering from the outside and noise emitted to the outside. An example of such a shield layer is a sheath layer that covers the outer periphery of the core wire using a material obtained by dispersing a powdery magnetic material in an organic polymer. Communication electric wires including such sheath layers containing magnetic materials are disclosed in Patent Documents 1 and 2, for example.

### PRIOR ART DOCUMENT

### Patent Document

Patent Document 1: JP 2016-197509 A
Patent Document 2: JP H03-088214 A

### SUMMARY OF THE INVENTION

### Problems to be Solved

In the case where a magnetic sheath layer in which a magnetic material powder is dispersed in an organic polymer is provided on the outer periphery of a communication electric wire, the magnetic sheath layer needs to contain a large amount of magnetic material in order to achieve sufficiently high noise shielding performance. If the magnetic sheath layer contains a large amount of magnetic material, however, the material structure of the magnetic sheath layer becomes brittle and the wear resistance decreases. In particular, when the communication electric wire is used in an environment in which it is frequently subjected to vibration while in contact with another member, such as in an automobile, the vibration causes friction between the magnetic sheath layer and the other member, as a result of which the surface of the magnetic sheath layer may be scraped off due to wear. This decreases the noise shielding effect realized by the magnetic sheath layer.

In view of the above, an object is to provide a communication electric wire including a magnetic sheath layer that contains a powdery magnetic material and has high wear resistance.

### Means to Solve the Problem

A communication electric wire according to the present disclosure includes: a conductor; an insulating layer covering an outer periphery of the conductor; and a magnetic sheath layer covering an outside of the insulating layer, wherein the magnetic sheath layer contains an organic polymer and a magnetic material, the magnetic sheath layer contains 15 parts by mass or more of an acid-modified polymer in 100 parts by mass of the entire organic polymer, and the magnetic material is composed of particles with an average particle diameter of 50 μm or less, and a content of the magnetic material in the magnetic sheath layer is 300 parts by mass or more with respect to 100 parts by mass of the entire organic polymer.

### Effect of the Invention

The communication electric wire according to the present disclosure is a communication electric wire including a magnetic sheath layer that contains a powdery magnetic material and has high wear resistance.

### BRIEF DESCRIPTION OF THE DRAWINGS

FIG. 1 is a cross-sectional view showing the structure of a communication electric wire according to an embodiment of the present disclosure.

### DETAILED DESCRIPTION TO EXECUTE THE INVENTION

### Description of Embodiments of Disclosure

First, embodiments of the present disclosure will be described below.

A communication electric wire according to the present disclosure includes: a conductor; an insulating layer covering an outer periphery of the conductor; and a magnetic sheath layer covering an outside of the insulating layer, wherein the magnetic sheath layer contains an organic polymer and a magnetic material, the magnetic sheath layer contains 15 parts by mass or more of an acid-modified polymer in 100 parts by mass of the entire organic polymer, and the magnetic material is composed of particles with an average particle diameter of 50 μm or less, and a content of the magnetic material in the magnetic sheath layer is 300 parts by mass or more with respect to 100 parts by mass of the entire organic polymer.

The communication electric wire contains the acid-modified polymer as the organic polymer in the magnetic sheath layer, and the content of the acid-modified polymer is 15 parts by mass or more with respect to 100 parts by mass of the entire organic polymer. The acid-modified polymer functions as a component that enhances the breaking strength of the magnetic sheath layer. Consequently, even when the magnetic sheath layer is subject to friction with an external material, the resin shavings containing the magnetic material and scraped off during wear are fine. Since the resin shavings scraped off are fine, a decrease in the noise shielding effect in parts where the magnetic sheath layer is scraped off as bulky resin shavings can be suppressed. Moreover, fine resin shavings densely accumulate in the recesses formed due to wear, with it being possible to suppress the entrance and emission of electromagnetic waves through the recesses. Limiting the average particle diameter of the magnetic material to 50 μm or less also contributes to finer resin shavings. In the communication electric wire, despite 300 parts by mass or more of the magnetic material being contained in the magnetic sheath layer with respect to 100 parts by mass of the organic polymer, the magnetic sheath layer has excellent wear resistance because bulky resin shavings are unlikely to be generated when the magnetic sheath layer is subjected to friction with an external member and is worn and thus a decrease in the noise shielding effect due to wear is suppressed, as mentioned above.

Preferably, the content of the acid-modified polymer in the magnetic sheath layer is 25 parts by mass or less with respect to 100 parts by mass of the entire organic polymer. Thus, an excessive increase in the degree of crystallinity caused by a large amount of acid-modified polymer being contained in the magnetic sheath layer can be prevented, and the low-temperature resistance of the magnetic sheath layer can be enhanced.

Preferably, the magnetic sheath layer contains an elastomer in addition to the acid-modified polymer, as the organic polymer. The elastomer has high breaking elongation. The use of the elastomer together with the acid-modified polymer as the material of the magnetic sheath layer can effectively improve the wear resistance of the magnetic sheath layer.

Preferably, the magnetic sheath layer has a tensile stress at break of 20 MPa or more. Since the magnetic sheath layer has high breaking strength, the resin shavings generated when the magnetic sheath layer is subjected to friction with an external member are fine, so that high wear resistance is achieved.

Preferably, the magnetic sheath layer has a breaking elongation of 80% or less. An organic polymer-containing material having higher breaking elongation tends to have lower breaking strength. By limiting the breaking elongation of the magnetic sheath layer to 80% or less, high breaking strength can be ensured. Thus, by limiting the breaking elongation of the magnetic sheath layer so as not to be excessively high, the resin shavings generated during wear are made finer to enhance the wear resistance improvement effect.

Preferably, the magnetic sheath layer has a breaking elongation of 55% or more. If the breaking elongation of the magnetic sheath layer is reduced by, for example, adding a large amount of acid-modified polymer to the magnetic sheath layer, the low-temperature resistance of the magnetic sheath layer tends to decrease. By limiting the breaking elongation of the magnetic sheath layer to 55% or more, high low-temperature resistance of the magnetic sheath layer can be maintained.

Preferably, the communication electric wire is a coaxial electric wire including a metal shield layer on an outer periphery of the insulating layer, and the magnetic sheath layer is located on an outer periphery of the metal shield layer. A communication electric wire formed as a coaxial electric wire is susceptible to noise. Even in the case where a large amount of magnetic material is added to the magnetic sheath layer for the purpose of noise reduction, the magnetic sheath layer has high wear resistance, so that a decrease in noise shieldability caused by wear can be suppressed. The coaxial electric wire can thus be used for communication in a state in which the influence of noise is reduced.

### Details of Embodiments of the Present Disclosure

A communication electric wire according to an embodiment of the present disclosure will be described in detail below, with reference to the drawings. Various properties described below are values measured at room temperature in the atmosphere unless otherwise specified.

(Overall Structure of Communication Electric Wire)

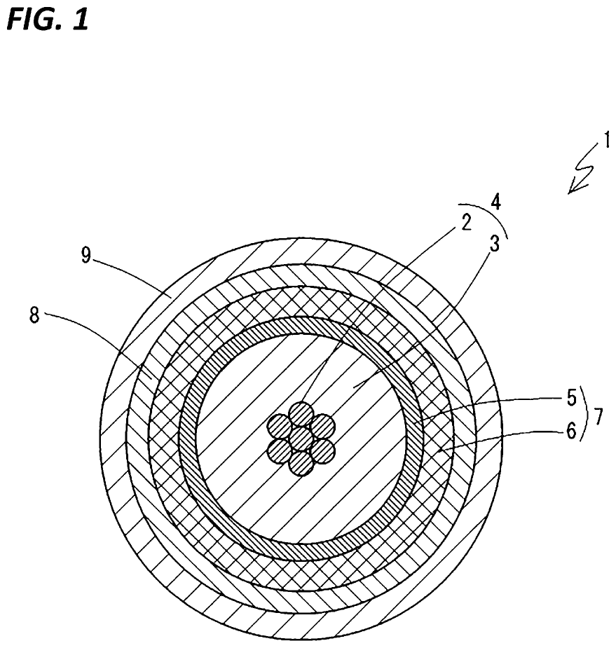

FIG. 1 is a cross-sectional view of a communication electric wire 1 according to an embodiment of the present disclosure, taken perpendicularly to the axial direction. The communication electric wire 1 is formed as a coaxial electric wire. Specifically, the communication electric wire 1 includes a core wire 4 including a conductor 2 and an insulating layer 3 covering the outer periphery of the conductor 2. A metal foil 5 and a braided layer 6 serving as a braided body formed by braiding metal strands are provided on the outer periphery of the core wire 4, as a metal shield layer 7. The metal foil 5 covers the outer periphery of the core wire 4, and the braided layer 6 covers the outer periphery of the metal foil 5. A magnetic sheath layer 8 containing a magnetic material is provided on the outer periphery of the metal shield layer 7. An outer sheath layer 9 not containing a magnetic material is provided on the outer periphery of the magnetic sheath layer 8.

In the communication electric wire 1 according to this embodiment, the magnetic sheath layer 8 contains at least a predetermined amount of acid-modified polymer, as described in detail later. Moreover, the particle diameter and content of the magnetic material contained in the magnetic sheath layer 8 are stipulated. As a result of the magnetic sheath layer 8 having such a component composition, even when the magnetic sheath layer 8 is subjected to friction with an external member, bulky resin shavings are unlikely to be generated due to wear. Consequently, high noise shielding performance is likely to be maintained.

The communication electric wire 1 formed as a coaxial electric wire having the metal shield layer 7 and the magnetic sheath layer 8 on the outer periphery of the core wire 4 can be suitably used for transmitting signals in a high frequency range of 1 GHz or higher. The communication electric wire according to the present disclosure is, however, not limited to the foregoing structure, as long as the magnetic sheath layer 8 covers the outside of the core wire 4, and may have a structure that corresponds to the communication frequency or the usage. The magnetic sheath layer 8 may cover the outer periphery of the core wire 4 directly, or cover the outer periphery of the core wire 4 with another layer, such as the metal shield layer 7, interposed therebetween.

For example, although a single insulated electric wire is used as the core wire 4 in this embodiment, a plurality of insulated electric wires may be used. Specifically, the core wire 4 may be configured to transmit differential signals by twisting a pair of insulated electric wires together or arranging a pair of insulated electric wires parallel to each other. In the case where the influence of noise is not significant, only one of the metal foil 5 and the braided layer 6 may be provided as the metal shield layer 7, or the metal shield layer 7 may be omitted. As the metal shield layer 7, members other than the metal foil 5 and the braided layer 6, such as a horizontally wound wire, may be used. The outer sheath layer 9 may be omitted if the need for the function of, for example, protecting the magnetic sheath layer 8 is not significant. Although each of the foregoing layers is formed in direct contact with the outer periphery of the constituent layer on the inner side thereof in this embodiment, the communication electric wire may include constituent layers other than the foregoing layers as appropriate. Each constituent member of the coaxial communication electric wire 1 will be described in detail below.

(Core Wire)

The core wire 4 is a signal wire having the function of transmitting electrical signals in the communication electric wire 1, and includes the conductor 2 and the insulating layer 3 covering the outer periphery of the conductor 2. The materials of the conductor 2 and the insulating layer 3 are not limited.

Various metal materials can be used as the material of the conductor 2. A copper alloy is preferable because of its high conductivity and the like. The conductor 2 may be formed as a single wire, but is preferably formed as a stranded wire obtained by twisting a plurality of (for example, seven) strands together, from the viewpoint of enhancing flexibility during bending, etc. In this case, after twisting the strands, compression molding may be performed to form a compressed stranded wire. In the case where the conductor 2 is formed as a stranded wire, the conductor 2 may be composed of strands of the same type or strands of two or more types. The diameter of the conductor 2 is not limited. The cross-sectional area of the conductor is, for example, in the range of 0.05 mm² or more and 1.0 mm² or less.

The insulating layer 3 insulates the conductor 2 in the core wire 4, and contains an organic polymer. The type of organic polymer is not limited, and examples include olefin-based polymers such as polyolefins and olefin-based copolymers, halogen-based polymers such as polyvinyl chloride, various engineering plastics, elastomers, and rubbers. These organic polymers may be used singly or in combination of two or more types through mixing, lamination, or the like. The organic polymer may be crosslinked or foamed.

Of the organic polymers listed above, a low-molecular-weight polar organic polymer is preferably used as the organic polymer contained in the insulating layer 3, from the viewpoint of enhancing the communication properties. For example, the insulating layer 3 preferably contains a non-polar organic polymer, e.g. a polyolefin such as polypropylene (PP). As the polyolefin, homopolyolefin such as homo PP or block polyolefin such as block PP may be used.

The insulating layer 3 may contain additives as appropriate, in addition to the organic polymer. Examples of the additives include flame retardants such as metal hydroxides, copper inhibitors, antioxidants such as hindered phenol-based and sulfur-based antioxidants, and metal oxides such as zinc oxide. It is preferable that the insulating layer 3 does not contain any additive made of a magnetic material such as the magnetic material contained in the magnetic sheath layer 8.

(Metal Shield Layer)

The metal shield layer 7 is located between the core wire 4 and the magnetic sheath layer 8, and has a two-layer structure in which the metal foil 5 and the braided layer 6 are laminated.

The metal foil 5 is formed as a thin film of a metal material. The type of metal forming the metal foil 5 is not limited, and examples include copper, copper alloys, aluminum, and aluminum alloys. The metal foil 5 may be made of one type of metal, or may be a laminate of layers of two or more types of metal. The metal foil 5 is not limited to an independent metal thin film, and may be formed by bonding a metal layer to a base material such as a polymer film through vapor deposition, plating, adhesion, or the like. The metal foil 5 is preferably disposed along the core wire 4 in the longitudinal direction, from the viewpoint of enhancing the noise shieldability.

The braided layer 6 is formed as a braided body obtained by twisting a plurality of metal strands together to form a hollow tubular shape. Examples of the metal strands forming the braided layer 6 include metal materials such as copper, copper alloys, aluminum, and aluminum alloys, and such metal materials whose surfaces are plated with tin or the like.

The metal shield layer 7 constitutes the outer conductor in the coaxial electric wire structure, and has the function of shielding noise entering the core wire 4 and noise emitted from the core wire 4. In the communication electric wire 1, the noise shielding effect is also exhibited by the magnetic sheath layer 8, as described later. However, in the case where the communication electric wire 1 is used for communication in a high frequency range such as 1 GHz or higher, the influence of noise tends to be serious, and providing the metal shield layer 7 together with the magnetic sheath layer 8 can effectively reduce the influence of noise. By using both the metal foil 5 and the braided layer 6 as the metal shield layer 7, the noise shielding effect can be enhanced. Although the order of lamination of the metal foil 5 and the braided layer 6 is not limited, it is preferable to dispose the metal foil 5 on the inner side and the braided layer 6 on the outer side for reasons such as reducing signal loss.

(Magnetic Sheath Layer)

The magnetic sheath layer 8 covers the outer periphery of the core wire 4. In this embodiment, the magnetic sheath layer 8 covers the outer periphery of the core wire 4 with the metal shield layer 7 interposed therebetween.

The magnetic sheath layer 8 contains a powdery magnetic material and an organic polymer component. The magnetic material powder is dispersed in a matrix formed by the organic polymer component. The magnetic material contained in the magnetic sheath layer 8 is preferably a ferromagnetic material, and more preferably a metal or metal compound having soft magnetism. As a result of the magnetic sheath layer 8 containing a magnetic material, particularly a soft magnetic material, the communication electric wire 1 can achieve an excellent noise shielding effect. Specifically, it is possible to suppress a phenomenon in which electromagnetic waves enter the communication electric wire 1 from the outside and, become noise that affects the signals transmitted through the core wire 4, and a phenomenon in which electromagnetic waves caused by the signals transmitted through the core wire 4 are emitted to the outside of the communication electric wire 1. This is because high-frequency electromagnetic waves which can cause noise are absorbed and attenuated by magnetic loss in the magnetic material contained in the magnetic sheath layer 8. In the communication electric wire 1, the noise shielding effect is also exhibited by the metal foil 5 and the braided layer 6. However, in the case where the communication electric wire 1 is used for communication in a high frequency range such as 1 GHz or higher, the influence of noise tends to be serious, and providing the magnetic sheath layer 8 together with the metal foil 5 and the braided layer 6 can effectively reduce the influence of noise.

(1) Magnetic Material

Examples of soft magnetic materials that exhibit high noise shieldability in high frequency regions such as 1 GHz or higher include iron (pure iron or iron containing a small amount of carbon), an Fe—Si-based alloy (silicon steel), an Fe—Si—Al alloy (Sendust), magnetic stainless steels such as an Fe—Cr—Al—Si alloy and an Fe—Si—Cr alloy, an Fe—Ni-based alloy (Permalloy), and ferrite. Of these materials, it is particularly preferable to use ferrite because of its excellent noise shieldability and low cost. As the ferrite, Ni—Zn-based ferrite is particularly suitable. These magnetic materials may be used alone or in combination of two or more types by mixing or the like.

The particles of the magnetic material contained in the magnetic sheath layer 8 have an average particle diameter (D50 value of equivalent circle diameter in electron microscope observation) of 50 μm or less. If the particle diameter of the magnetic material is excessively large, the structure of the composite material in which the magnetic material is dispersed in the organic polymer component is brittle. In such a case, it is likely that bulky resin shavings (a powder of the organic polymer containing the magnetic material) will be formed by the magnetic material together with the organic polymer component and scraped off from the magnetic sheath layer 8. However, by limiting the average particle diameter of the magnetic material to 50 μm or less, the affinity between the magnetic material and the organic polymer component increases, and the adhesion between the magnetic material and the organic polymer component increases. Hence, even when the magnetic sheath layer 8 is subjected to friction with an external member, wear accompanied by generation of resin shavings is unlikely to occur. Even in the case where wear occurs and resin shavings are formed, the resin shavings are fine. The magnetic material having an average particle diameter of 50 μm or less also exhibits an excellent noise shielding effect. The average particle diameter of the magnetic material is more preferably 45 μm or less and more preferably 30 μm or less, from the viewpoint of making the resin shavings finer and further enhancing the noise shielding performance improvement effect. The magnetic material is preferably dispersed in the organic polymer component without forming secondary particles through aggregation or the like. In the case where the magnetic material forms secondary particles, however, not only the primary particle diameter but also the secondary particle diameter is preferably less than or equal to the foregoing upper limit.

No lower limit is particularly placed on the particle diameter of the magnetic material, but the average particle diameter of the magnetic material is preferably 0.1 μm or more and more preferably 0.5 μm or more from the viewpoint of suppressing the formation of bulky resin shavings and avoiding the saturation of the effect with which resin shavings are made finer and also from the viewpoint of ensuring the ease of handling of the magnetic material. The particle shape of the magnetic material is not particularly limited, either, and, for example, spherical, flat, or irregular particles may be used.

The content of the magnetic material in the magnetic sheath layer 8 is 300 parts by mass or more with respect to 100 parts by mass of the entire organic polymer component. As a result of the content of the magnetic material being 300 parts by mass or more with respect to 100 parts by mass of the organic polymer component, the magnetic sheath layer 8 exhibits high noise shielding performance. The content of the magnetic material is more preferably 350 parts by mass or more, from the viewpoint of enhancing the noise shielding performance of the magnetic sheath layer 8. In the case where the magnetic sheath layer 8 contains a large amount of magnetic material, when the magnetic sheath layer 8 is subjected to friction with an external member, bulky resin shavings tend to be generated due to wear. However, as a result of the average particle diameter of the magnetic material being suppressed to 50 μm or less as mentioned above and also as a result of at least a predetermined amount of an acid-modified polymer being included in the organic polymer component as described later, even in the case where the content of the magnetic material in the magnetic sheath layer 8 is 300 parts by mass or more, the generation of resin shavings is suppressed, and, even if resin shavings are generated, the resin shavings are fine. In the following description, the content of each component of the magnetic sheath layer 8 in units of parts by mass is expressed with respect to 100 parts by mass of the entire organic polymer component.

No upper limit is particularly placed on the content of the magnetic material, but the content is preferably 800 parts by mass or less. This makes it easy to exhibit the properties provided by the organic polymer component such as mechanical strength and the effect of making resin shavings finer, as the properties of the magnetic sheath layer 8 as a whole.

(2) Organic Polymer Component

The material of the magnetic sheath layer 8 contains an organic polymer. The organic polymer includes at least an acid-modified polymer. The content of the acid-modified polymer is 15 parts by mass or more with respect to 100 parts by mass of the entire organic polymer component.

As a result of the magnetic sheath layer 8 containing an acid-modified polymer and the content of the acid-modified polymer being 15 parts by mass or more, bulky resin shavings are unlikely to be generated from the magnetic sheath layer 8 due to friction with an external member. The reason for this is as follows. The acid-modified polymer has high breaking strength as a property of the material itself, and also has high affinity with the magnetic material due to its polarity and therefore exhibits high adhesiveness at the interface with the magnetic material particles. The acid-modified polymer is thus a material that effectively increases the breaking strength of the magnetic sheath layer 8. Since the magnetic sheath layer 8 has high breaking strength, even when the magnetic sheath layer 8 is subjected to friction with an external member, the magnetic sheath layer 8 is kept from being scraped off due to wear. Even if wear occurs, the high breaking strength of the magnetic sheath layer 8 allows the resin shavings generated due to wear to be torn off in a fine state and separated from the magnetic sheath layer 8 without being stretched greatly. These mechanisms prevent the generation of bulky resin shavings due to wear. From the viewpoint of further enhancing these effects, the content of the acid-modified polymer in the magnetic sheath layer 8 is more preferably 20 parts by mass or more.

No upper limit is placed on the content of the acid-modified polymer in the magnetic sheath layer 8. Given that the acid-modified polymer has a higher degree of crystallinity than an organic polymer having high breaking elongation, such as a later-described elastomer, if a large amount of the acid-modified polymer is contained in the magnetic sheath layer 8, the properties of the magnetic sheath layer 8 may decrease in a low-temperature environment. Accordingly, the content of the acid-modified polymer is preferably kept to 25 parts by mass or less from the viewpoint of ensuring the low-temperature resistance of the magnetic sheath layer 8 and suppressing damage such as cracks in a low-temperature environment.

Although the acid-modified polymer is not limited to any specific type, acid-modified polyolefins such as acid-modified polypropylene can be suitably used. Examples of the acid modification type include maleic acid modification and maleic anhydride modification. As the acid-modified polymer, an acid-modified polymer having a tensile stress at break of 20 MPa or more and 50 MPa or less and a breaking elongation of 10% or more and 200% or less can be suitably used. The tensile stress at break and breaking elongation of the polymer component composition can be evaluated by a tensile test in accordance with JIS K 7161. The acid-modified polymers may be used alone or in combination of two or more types.

The type of organic polymer contained in the magnetic sheath layer 8 other than the acid-modified polymer is not limited, and examples include olefin-based polymers such as polyolefins and olefin-based copolymers, halogen-based polymers such as polyvinyl chloride, various engineering plastics, elastomers, and rubbers. These organic polymers other than the acid-modified polymer may be used singly or in combination of two or more types.

In at least part of the organic polymers other than the acid-modified polymer contained in the magnetic sheath layer 8, it is preferable to use an organic polymer whose breaking elongation is greater than that of the acid-modified polymer. As the organic polymer having high breaking elongation, an elastomer can be suitably used. By using a material having high breaking elongation, such as an elastomer, together with the acid-modified polymer in the magnetic sheath layer 8, the effect of improving the wear resistance of the magnetic sheath layer 8 is particularly enhanced.

The type of the elastomer is not limited, and various thermoplastic elastomers such as olefin-based, styrene-based, vinyl chloride-based, urethane-based, and ester-based elastomers may be used. Of these, olefin-based thermoplastic elastomers (TPO) are particularly suitable. When a TPO is used together with the acid-modified polymer such as acid-modified polyolefin as the organic polymer component contained in the magnetic sheath layer 8, the effect of suppressing the generation of bulky resin shavings during wear is enhanced. The elastomer contained in the magnetic sheath layer 8 preferably has a breaking elongation of 200% or more and 1100% or less.

The content of the elastomer in the magnetic sheath layer 8 is preferably 45 parts by mass or more with respect to 100 parts by mass of the organic polymer component, from the viewpoint of sufficiently achieving the effect realized by the inclusion of the elastomer. The content of the elastomer is preferably 60 parts by mass or less, from the viewpoint of suppressing a decrease in the breaking strength of the magnetic sheath layer 8 caused by the inclusion of a large amount of the elastomer. In particular, it is preferable to use two or more different types of elastomers in combination. More preferably, a first elastomer having a breaking elongation of 200% or more and 400% or less and a second elastomer having a breaking elongation of 900% or more and 1100% or less are used as two types of elastomers, and the content of the first elastomer is 30 parts or less with respect to 100 parts of the organic polymer component and the content of the second elastomer is less than or equal to that of the first elastomer.

It is also preferable to use, as an organic polymer other than the acid-modified polymer contained in the magnetic sheath layer 8, an unmodified polyolefin in addition to the elastomer. The use of an unmodified polyolefin has the effect of improving the fluidity of the resin and improving the extrusion moldability. As the unmodified polyolefin, polypropylene or the like can be suitably used. The unmodified polyolefin may be homopolyolefin or block polyolefin. The content of the unmodified polyolefin in the magnetic sheath layer 8 is preferably 10 parts by mass or more and 50 parts by mass or less with respect to 100 parts by mass of the organic polymer component.

The magnetic sheath layer 8 may contain an additive as appropriate, in addition to the magnetic material and the organic polymer. Examples of the additive include flame retardants, copper inhibitors, antioxidants, and metal oxides. The average particle diameters of these additives are preferably limited to 50 μm or less, as with the magnetic material.

The thickness of the magnetic sheath layer 8 is not limited, but is preferably 0.10 mm or more from the viewpoint of sufficiently enhancing the noise shielding effect and the wear resistance. The thickness of the magnetic sheath layer 8 is preferably 0.50 mm or less, from the viewpoint of ensuring the bending flexibility and the like.

(3) Properties of Magnetic Sheath Layer

As described above, the magnetic sheath layer 8 contains an acid-modified polymer as the organic polymer component, and the content of the acid-modified polymer is 15 parts by mass or more with respect to 100 parts by mass of the organic polymer component. Such a magnetic sheath layer has high breaking strength, despite containing 300 parts by mass or more of the magnetic material. Since the magnetic sheath layer 8 has high breaking strength, even when the magnetic sheath layer 8 is subjected to friction with an external member, the surface of the magnetic sheath layer 8 is unlikely to be scraped off due to wear. Even if wear occurs, the resin shavings generated due to the wear tend to be fine. Limiting the average particle diameter of the magnetic material contained in the magnetic sheath layer 8 to 50 μm or less also contributes to finer resin shavings.

If bulky resin shavings are generated due to wear and separate from the magnetic sheath layer 8, the noise shielding performance may deteriorate in the parts where the magnetic sheath layer 8 has been scraped off as the resin shavings. If the resin shavings generated are fine, on the other hand, such local deterioration of the noise shielding performance can be prevented. Even in the case where the surface of the magnetic sheath layer 8 is scraped off due to wear and recesses are formed, if the resin shavings generated due to wear are fine, the generated resin shavings enter the recesses and densely accumulate so as to fill the recesses. This prevents electromagnetic waves acting as noise from entering or being emitted from the communication electric wire 1 through the recesses, and thus high noise shielding performance of the magnetic sheath layer 8 is maintained. Thus, as a result of adding a predetermined amount of acid-modified polymer to the magnetic sheath layer 8, even when the magnetic sheath layer 8 is subjected to friction, bulky resin shavings are unlikely to be generated. Hence, the wear resistance of the magnetic sheath layer 8 is improved, and the magnetic sheath layer 8 maintains high noise shielding performance even when subjected to friction. In general, if the major axis (i.e. the length of the longest straight line that crosses the resin shaving) of the resin shavings generated due to wear of the magnetic sheath layer 8 is 400 μm or less, the noise shieldability is effectively maintained by the accumulation of the resin shavings in the recesses. If the generated resin shavings are bulky, the resin shavings cannot fit into the recesses so as to densely close off the recesses unlike fine resin shavings, and thus the noise shieldability cannot be effectively maintained.

The wear resistance of the magnetic sheath layer 8 can be improved not only by using an organic polymer having high breaking strength as the organic polymer component contained in the magnetic sheath layer 8 as mentioned above but also by using an organic polymer having high breaking elongation as the organic polymer component contained in the magnetic sheath layer 8. Here, an improvement in the wear resistance due to the improvement of the breaking strength is achieved by suppressing wear and fining the resin shavings generated during wear, whereas the improvement in the wear resistance due to the improvement of the breaking elongation is achieved by causing resin shavings in the process of generation to remain connected to the magnetic sheath layer 8 without separating from the magnetic sheath layer 8. Regarding the size of the resin shavings generated, the resin shavings are rather bulky because the breaking elongation of the organic polymer component is high and the resin shavings in the process of generation are dragged and stretched during friction. Even in the case where bulky resin shavings are generated and they remain in a state of not separating from the magnetic sheath layer 8, the bulky resin shavings are unlikely to densely fill the recesses caused by wear, and do not effectively contribute to suppressing the decrease in noise shieldability due to wear.

Thus, the improvement in the wear resistance due to the improvement in the breaking strength of the organic polymer component and the improvement in the wear resistance due to the improvement of the breaking elongation result from creating different states on the surface of the magnetic sheath layer 8 using different mechanisms. The improvement in the breaking elongation does not contribute to the phenomenon of making the resin shavings finer, which is effective in suppressing the decrease in noise shieldability. Typically, an organic polymer having high breaking elongation tends to have low breaking strength. In this embodiment, as a result of the content of the acid-modified polymer serving as the organic polymer component contained in the magnetic sheath layer 8 being 15 parts by mass or more with respect to 100 parts by mass of the organic polymer component, the content of organic polymers that can have high breaking elongation, such as elastomers, is kept relatively low. This allows the magnetic sheath layer 8 as a whole to have high breaking strength at the expense of reduced breaking elongation. Thus, the wear resistance is effectively improved in terms of making finer resin shavings generated due to wear and maintaining the noise shieldability during wear as a result of making the resin shavings finer. The communication electric wire 1 according to this embodiment is, even when subjected to friction while in contact with another member, prevented from deterioration in noise shielding performance due to wear of the magnetic sheath layer 8, and therefore is suitable for use in environments in which it is frequently subjected to vibration while in contact with another member, such as in an automobile.

Moreover, high low-temperature resistance of the magnetic sheath layer 8 can be maintained by limiting the content of the acid-modified polymer in the magnetic sheath layer 8 to 25 parts by mass or less, as mentioned above. In the case where the communication electric wire 1 is used in an automobile, it is also expected that the communication electric wire 1 will be exposed to a low-temperature environment. Hence, the communication electric wire 1 preferably has high low-temperature resistance as well as high wear resistance. Here, the communication electric wire 1 according to the present disclosure need not necessarily have high low-temperature resistance. For example, the communication electric wire 1 may not have high low-temperature resistance in the case where it is not expected to be used in a low-temperature environment.

The breaking strength of a material can be evaluated by the tensile stress at break. The tensile stress at break of the magnetic sheath layer 8 as a whole is preferably 20 MPa or more and more preferably 24 MPa or more, from the viewpoint of enhancing the effect of suppressing wear and making resin shavings of the magnetic sheath layer 8 finer. The tensile stress at break of the magnetic sheath layer 8 as a whole is preferably 28 MPa or less, from the viewpoint of suppressing a decrease in low-temperature resistance caused by the inclusion of a large amount of components that increase the tensile stress at break, such as acid-modified polymers.

As mentioned above, an organic polymer having high breaking elongation, such as an elastomer component, does not contribute to finer resin shavings generated during wear but rather makes the resin shavings of the magnetic sheath layer 8 bulky. However, such an organic polymer contributes to suppression of wear of the magnetic sheath layer 8 by a mechanism different from that of the acid-modified polymer. The organic polymer having high breaking elongation also compensates for the decrease in the low-temperature resistance caused by the inclusion of the acid-modified polymer, and contributes to improved low-temperature resistance. Therefore, having limited the content of the acid-modified polymer to 15 parts by mass or more with respect to 100 parts by mass of the organic polymer component in the magnetic sheath layer 8 in this embodiment to thus relatively restrict the content of the other components, an organic polymer having high breaking elongation such as an elastomer component may be contained as another component. Such a magnetic sheath layer 8 can effectively achieve both high wear resistance and high low-temperature resistance. From the viewpoint of enhancing these effects, the breaking elongation of the magnetic sheath layer 8 as a whole is preferably 55% or more. From the viewpoint of avoiding impeding the effect of making finer resin shavings due to excessively high breaking elongation of the magnetic sheath layer 8, the breaking elongation of the magnetic sheath layer 8 as a whole is preferably 80% or less, and more preferably 75% or less.

(Outer Sheath Layer)

The outer sheath layer 9 is a layer that covers the outer periphery of the magnetic sheath layer 8, and is exposed on the outer periphery of the communication electric wire 1 as a whole. The outer sheath layer 9 contains no magnetic material except for inevitable impurities.

The outer sheath layer 9 has the function of physically protecting the magnetic sheath layer 8 and the inner constituent members from contact with external objects and the like. As mentioned above, the component composition of the magnetic sheath layer 8 is set to make the resin shavings generated due to wear finer, and therefore such wear that decreases the noise shieldability is unlikely to occur even when the magnetic sheath layer 8 comes in contact with an external object. Hence, from the viewpoint of sufficiently suppressing wear of the magnetic sheath layer 8, the outer sheath layer 9 may be omitted. However, by protecting the magnetic sheath layer 8 with the outer sheath layer 9, the magnetic sheath layer 8 is further prevented from wear, and higher noise shielding performance can be more easily maintained. The inclusion of the magnetic material in the magnetic sheath layer 8 may cause an increase in hardness and facilitate damage such as cracks or splits. Even in the case where damage such as cracks or splits occurs in the magnetic sheath layer 8, such damage can be kept from propagating and leading to the formation of large voids because the magnetic sheath layer 8 is covered by the outer sheath layer 9. This suppresses a situation in which propagation of damage causes voids to form on the surface of the magnetic sheath layer 8 and electromagnetic waves leak through the voids, leading to a decrease in the noise shielding performance of the magnetic sheath layer 8.

The outer sheath layer 9 preferably contains an organic polymer. Specific examples of the organic polymer include olefin-based polymers such as polyolefins and olefin-based copolymers, halogen-based polymers such as polyvinyl chloride, various engineering plastics, elastomers, and rubbers, as with the organic polymer contained in the insulating layer 3 and the organic polymer contained in the magnetic sheath layer 8. Of these, olefin-based polymers, particularly TPO, are preferable because of their excellent insulating properties and heat resistance. These organic polymers may be used alone or in combination of two or more types through mixing, lamination, or the like. The organic polymer may be crosslinked or foamed. Preferably, the same organic polymer as at least some of the organic polymers contained in the magnetic sheath layer 8 is contained in the outer sheath layer 9, from the viewpoint of enhancing the adhesiveness between the magnetic sheath layer 8 and the outer sheath layer 9. It is particularly preferable that the same elastomer as that contained in the magnetic sheath layer 8 is also contained in the outer sheath layer 9.

The thickness of the outer sheath layer 9 is not limited, but is preferably 0.10 mm or more from the viewpoint of enhancing the performance of protecting the magnetic sheath layer 8, etc. The thickness of the outer sheath layer 9 is preferably 0.50 mm or less from the viewpoint of enhancing the flexibility, etc.

### Examples

Examples will be described below. The present disclosure is not limited to these examples. In the examples, the evaluation of each property was performed at room temperature in the atmosphere unless otherwise specified.

[Production of Communication Electric Wire]

A core wire was produced by forming an insulating layer by performing extrusion molding on the outer periphery of a conductor formed as a copper alloy stranded wire. As the material of the insulating layer, the mixture of the components indicated as “insulating layer” in Table 1 below was used. The cross-sectional area of the conductor was 0.18 mm², and the thickness of the insulating layer was 0.54 mm.

A copper foil was provided on the outer periphery of the core wire along the core wire in the longitudinal direction, as a metal foil. Further, a braided layer was formed on the outer periphery of the copper foil. The braided layer was a single braid made of a tin-plated annealed copper wire (TA wire).

A magnetic sheath layer was formed on the outer periphery of the braided layer. As the magnetic sheath layer, the mixture of the organic polymer and the magnetic material powder shown in Tables 2 and 3 below was extruded to a thickness of 0.20 mm in each of samples A1 to A11 and B1 to B7. In samples A1 to A11, the mix proportion of each component was changed. In samples B1 to B7, different magnetic materials were added.

In each sample, an outer sheath layer was also formed on the outer periphery of the magnetic sheath layer through extrusion molding to complete a communication electric wire. The thickness of the outer sheath layer was 0.20 mm. As the material of the outer sheath layer, the mixture of the components indicated as “outer sheath layer” in Table 1 below was used for all samples.

The following materials were used as the components contained in the insulating layer, the magnetic sheath layer, and the outer sheath layer. The breaking elongation and the tensile stress at break are also shown for each organic polymer used in the magnetic sheath layer from among the organic polymers.

(Organic Polymers)
TPO1: TPO “Adflex Q200F” manufactured by LyondellBasell, breaking elongation: 350%, tensile stress at break: 11 MPa.
TPO2: TPO “SANTOPRENE 203-40” manufactured by Exxon Mobil Corporation.
TPO3: TPO “TAFMER PN-20300” manufactured by Mitsui Chemicals, Inc., breaking elongation: 1080%, tensile stress at break: 21 MPa.
Block PP1: Block PP “NOVATEC EC9GD” manufactured by Japan Polypropylene Corporation.
Block PP2: Block PP “NOVATEC BC06C” manufactured by Japan Polypropylene Corporation, breaking elongation: 10%, tensile stress at break: 40 MPa.
Homo PP: “NOVATEC EA9FTD” manufactured by Japan Polypropylene Corporation.
Acid-modified SEBS: “TUFTEC M1913” manufactured by Asahi Kasei Corporation.
Maleic acid-modified PP: “ADMER QE820” manufactured by Mitsui Chemicals, Inc., breaking elongation: 82%, tensile stress at break: 22 MPa.

(Magnetic Materials)
As Ni—Zn ferrite, the following products with three types of particle diameters (average particle diameters) were used. The particle shape of each product is an irregular shape including uneven spheres. All products are manufactured by JFE Chemical Corporation.
“KNI-109”: particle diameter: 0.8 mm.
“KNI-109GSM”: particle diameter: 21 mm.
“KNI-109GS”: particle diameter: 100 mm.
   Fe—Si—Cr alloy: “AKT-7” manufactured by Mitsubishi Steel Mfg. Co., Ltd. (particle shape: sphere without unevenness, particle diameter: 10 μm).
   As an Fe—Si—Al alloy, the following products with two types of particle diameters were used. The particle shape of each product is flat. All products are manufactured by Sanyo Special Steel Co., Ltd.
“High magnetic permeability fine powder type”: particle diameter: 30 μm.
“High magnetic permeability type B”: particle diameter: 45 μm.
   Fe—Si-based alloy: “High magnetic permeability standard type” manufactured by Sanyo Special Steel Co., Ltd. (particle shape: flat, particle diameter: 60 μm).

(Other Additives)
Copper inhibitor: “CDA-1” manufactured by ADEKA Corporation.
Hindered phenol-based antioxidant: “Irganox 1010FF” manufactured by BASF SE.
   Sulfur-based antioxidant: “ANTAGE MB” (2-mercaptobenzimidazole) manufactured by Kawaguchi Chemical Industry Co., Ltd.
Zinc oxide: “Type 2 Zinc Oxide” manufactured by Hakusui Tech Co., Ltd.
   Flame retardant: “KISUMA 5” (magnesium hydroxide) manufactured by Kyowa Chemical Industry Co., Ltd.

The component compositions of the materials used to produce the insulating layer and the outer sheath layer in all samples are shown in parts by mass in Table 1.

TABLE 1

| Component | Insulating layer | Outer sheath layer |
|---|---|---|
| TPO1 | — | 60.0 |
| TPO2 | — | 30.0 |
| Block PP1 | 50.0 | — |
| Homo PP | 48.0 | — |
| Acid-modified SEBS | 2.0 | 10.0 |
| Copper inhibitor | 0.5 | — |
| Hindered phenol-based | 1.2 | 2.0 |
| antioxidant | | |
| Sulfur-based antioxidant | 0.8 | — |
| Zinc oxide | 0.8 | — |
| Flame retardant | 0.8 | 120.0 |

[Evaluation]

(1) Noise Shieldability

The noise shieldability was evaluated for each of the communication electric wires of samples A1 to A11 and samples B1 to B7. As the evaluation, radiated emission evaluation in accordance with CISPR 25 (the standard of “Radio Disturbance Characteristics-Limits and Methods of Measurement for the Protection of On-Board Receivers” by the International Special Committee on Radio Interference (CISPR)) was conducted. Specifically, in an anechoic chamber, a horn antenna was installed at a position 1.0 m laterally away from the center part of the communication electric wire cut to 1500 mm. An electrical signal with a frequency of 1.6 GHz was then input to the communication electric wire, and the amount of noise emission was measured by the horn antenna. In the case where the amount of noise emission was less than 16 dB (μV/m), the noise shieldability was evaluated as especially high, rated “A+”. In the case where the amount of noise emission was 16 dB (μV/m) or more and less than 22 dB (μV/m), the noise shieldability was evaluated as high, rated “A”. In the case where the amount of noise emission was 22 dB (μV/m) or more, the noise shieldability was evaluated as low, rated “B”. The evaluation was performed on the initial state of the communication electric wire produced and the state after a wear test was conducted. In the wear test, an iron wire with an outer diameter of 0.45 mm was pressed against the side of the communication electric wire with a load of 7 N and reciprocated 100 times.

(2) Tensile Properties of Magnetic Sheath Layer

The breaking elongation and tensile stress at break of the magnetic sheath layers in each of the samples A1 to A11 were measured using a tensile test in accordance with JIS K 7161. A test piece to be measured was made as follows: during the formation of the communication electric wire as described above, the internal core wire, metal foil, and the braided layer were pulled out and removed from the electric wire at the stage when the formation of the magnetic sheath layer was completed.

(3) Size of Resin Shavings

For the samples A1 to A11, in the wear test conducted as part of the noise shieldability test, resin shavings generated from the magnetic sheath layer were collected and observed under a microscope. The major axis of the resin shaving whose major axis (longest straight line that crosses the resin shaving) was the longest of the resin shavings was recorded as the size of the resin shavings.

(4) Low-Temperature Resistance

For the samples A1 to A11, a low-temperature winding test was conducted in order to evaluate the low-temperature resistance. Specifically, the communication electric wire was wound around a stainless steel round bar having the same outer diameter as the electric wire, and left at a low temperature of −40° C. for 4 hours. The surface of the magnetic sheath layer was then visually observed. In the case where no cracks occurred, the low-temperature resistance was evaluated as high, rated “A”. In the case where cracks occurred, the low-temperature resistance was evaluated as low, rated “B”.

[Results]

For each of the samples A1 to A11 that differed in the mix proportion of each component of the magnetic sheath layer, the component composition (unit: parts by mass) of the magnetic sheath layer and the evaluation results are respectively shown in the upper and lower parts in Table 2. For each of samples B1 to B7 that differed in the magnetic material added to the magnetic sheath layer, the component composition (unit: parts by mass) of the magnetic sheath layer and the noise shieldability evaluation results are respectively shown in the upper and lower parts in Table 3. In Tables 2 and 3, the blending amount of each component is expressed with respect to 100 parts by mass of the total of the organic polymer components. Sample A7 and sample B1 are the same.

TABLE 2

| | | | Sample No. | | | | | | | | | | |
|---|---|---|---|---|---|---|---|---|---|---|---|---|---|
| | | | A1 | A2 | A3 | A4 | A5 | A6 | A7 | A8 | A9 | A10 | A11 |
| Components | TPO1 | | 30 | 30 | 30 | 30 | 30 | 30 | 30 | 30 | 30 | 30 | 30 |
| | TPO3 | | 40 | 40 | 40 | 35 | 30 | 25 | 20 | 15 | 10 | 5 | 0 |
| | Block PP2 | | 30 | 30 | 30 | 30 | 30 | 30 | 30 | 30 | 30 | 30 | 30 |
| | Maleic acid-modified PP | | 0 | 0 | 0 | 5 | 10 | 15 | 20 | 25 | 30 | 35 | 40 |
| | Ni—Zn ferrite (particle diameter 0.8 μm) | | 150 | 250 | 350 | 350 | 350 | 350 | 350 | 350 | 350 | 350 | 350 |
| Evaluation | Noise shieldability | Initial state | B | A | A⁺ | A⁺ | A⁺ | A⁺ | A⁺ | A⁺ | A⁺ | A⁺ | A⁺ |
| results | | After wear test | B | B | B | B | B | A⁺ | A⁺ | A⁺ | A⁺ | A⁺ | A⁺ |

| | | | | | | | | | | | |
|---|---|---|---|---|---|---|---|---|---|---|---|
| Breaking elongation [%] | 325 | 189 | 108 | 94 | 87 | 74 | 62 | 58 | 52 | 43 | 36 |
| Tensile stress at break [MPa] | 14.1 | 15.3 | 16.1 | 18.4 | 19.4 | 22.8 | 24.5 | 27.3 | 28.9 | 30.2 | 32.4 |
| Size of resin shavings [μm] | 3000 | 1700 | 700 | 600 | 500 | 380 | 300 | 120 | 100 | 75 | 50 |
| Low-temperature resistance | A | A | A | A | A | A | A | A | B | B | B |

TABLE 3

| | Particle | Sample No. | | | | | | |
|---|---|---|---|---|---|---|---|---|
| Material type | diameter [μm] | B1 | B2 | B3 | B4 | B5 | B6 | B7 |
| TPO1 | — | 30 | | | | | | |
| TPO3 | — | 20 | | | | | | |
| Block PP2 | — | 30 | | | | | | |
| Maleic acid- | — | 20 | | | | | | |
| modified PP | | | | | | | | |
| Ni—Zn ferrite | 0.8 | 350 | — | — | — | — | — | — |
| | 21 | — | 350 | — | — | — | — | — |
| | 100 | — | — | 350 | — | — | — | — |
| Fe—Si—Cr alloy | 10 | — | — | — | 350 | — | — | — |
| Fe—Si—Al alloy | 30 | — | — | — | — | 350 | — | — |
| | 45 | — | — | — | — | — | 350 | — |
| Fe—Si-based alloy | 60 | — | — | — | — | — | — | 350 |
| Noise shieldability | Initial state | A⁺ | A⁺ | A⁺ | A⁺ | A⁺ | A⁺ | A⁺ |
| | After wear test | A⁺ | A⁺ | B | A⁺ | A⁺ | A⁺ | B |

As shown in Table 2, in samples A1 and A2 in which the content of the magnetic material was less than 300 parts by mass, the noise shieldability was low (B) from the initial state before the wear test. In samples A3 to A11 in which the content of the magnetic material was 300 parts by mass or more, the noise shieldability was high (A+) in the initial state. These results demonstrate that the content of the magnetic material in the magnetic sheath layer needs to be 300 parts by mass or more with respect to 100 parts by mass of the organic polymer component in order to achieve sufficiently high noise shieldability in the communication electric wire.

Of samples A3 to A11 having high noise shieldability in the initial state, in samples A3 to A5 not containing maleic acid-modified PP or containing only less than 15 parts by mass of maleic acid-modified PP, the noise shieldability evaluation result worsened (B) after the wear test. In samples A6 to A11 containing 15 parts by mass or more of maleic acid-modified PP, high noise shielding performance (A+) was maintained even after the wear test. Regarding the size of the resin shavings generated in the wear test, the fineness of the resin shavings increased from sample A3 to sample A11, i.e. the resin shavings became finer as the content of maleic acid-modified PP increased. In samples A6 to A11 in which the content of maleic acid-modified PP was 15 parts by mass or more, the size of resin shavings was 400 μm or less. These results demonstrate that, as a result of the content of the acid-modified polymer in the magnetic sheath layer being 15 parts by mass or more with respect to 100 parts by mass of the organic polymer component, the fineness of the resin shavings generated during wear is increased to a major axis of 400 μm or less, contributing to high wear resistance that allows excellent noise shieldability to be maintained even after the wear test. In samples A6 to A11, the breaking elongation of the magnetic sheath layer was limited to 80% or less, and the tensile stress at break of the magnetic sheath layer was 20 MPa or more. These physical properties can serve as indexes for improvement in tensile strength by the inclusion of a sufficient amount of acid-modified polymer and the resultant fining of resin shavings.

As shown in Table 3, in all samples using different magnetic materials, the noise shieldability was high (A+) in the initial state before the wear test. In samples B3 and B7 in which the particle diameter of the magnetic material was larger than 50 μm, the noise shieldability was low (B) after the wear test. In samples Bi, B2, and B4 to B6 in which the particle diameter of the magnetic material was 50 μm or less, high noise shieldability (A+) was maintained even after the wear test. These results demonstrate that, as a result of the particle diameter of the magnetic material being 50 μm or less, the wear resistance of the magnetic sheath layer increases and high noise shieldability is maintained even after wear. The magnetic materials used in samples B1 to B7 differ in chemical composition and also differ in shape, such as irregular, spherical, and flat. In any case, however, high noise shieldability was maintained after the wear test when the particle diameter was 50 μm or less. This indicates that the improvement in wear resistance depends on the particle diameter rather than on the chemical composition or shape of the magnetic material.

As shown in Table 2, in all of samples A6 to A11 containing 15 parts by mass or more of maleic acid-modified PP with respect to 100 parts by mass of the organic polymer component, high wear resistance that allows high noise shieldability to be maintained even after the wear test (A+) was obtained, as mentioned above. However, the low-temperature resistance was low (B) in samples A9 to A11 in which the content of maleic acid-modified PP was 30 parts by mass or more. In samples A6 to A8 in which the content of maleic acid-modified PP was 25 parts by mass or less, on the other hand, high low-temperature resistance (A) was obtained. From these results, it can be understood that high wear resistance and high low-temperature resistance can be achieved by limiting the content of the acid-modified polymer in the magnetic sheath layer to 15 parts by mass or more and 25 parts by mass or less. In samples A6 to A8, the breaking elongation of the magnetic sheath layer was 55% or more, and the tensile stress at break was 28 MPa or less. These physical properties can serve as indexes for improvement in low-temperature resistance by limiting the content of the acid-modified polymer.

While the embodiments of the present disclosure have been described in detail above, the present disclosure is not limited to the foregoing embodiments, and various modifications are possible without departing from the gist of the present invention.

### LIST OF REFERENCE NUMERALS

1 Communication electric wire
2 Conductor
3 Insulating layer
4 Core wire
5 Metal foil
6 Braided layer
7 Metal shield layer
8 Magnetic sheath layer
9 Outer sheath layer

1. A communication electric wire comprising:
a conductor;
an insulating layer covering an outer periphery of the conductor; and
a magnetic sheath layer covering an outside of the insulating layer,
wherein the magnetic sheath layer contains an organic polymer and a magnetic material,
the magnetic sheath layer contains 15 parts by mass or more of an acid-modified polymer in 100 parts by mass of the entire organic polymer, and
the magnetic material is composed of particles with an average particle diameter of 50 μm or less, and a content of the magnetic material in the magnetic sheath layer is 300 parts by mass or more with respect to 100 parts by mass of the entire organic polymer.

2. The communication electric wire according to claim 1,
wherein a content of the acid-modified polymer in the magnetic sheath layer is 25 parts by mass or less with respect to 100 parts by mass of the entire organic polymer.

3. The communication electric wire according to claim 1,
wherein the magnetic sheath layer contains an elastomer in addition to the acid-modified polymer, as the organic polymer.

4. The communication electric wire according to claim 1,
wherein the magnetic sheath layer has a tensile stress at break of 20 MPa or more.

5. The communication electric wire according to claim 1,
wherein the magnetic sheath layer has a breaking elongation of 80% or less.

6. The communication electric wire according to claim 1,
wherein the magnetic sheath layer has a breaking elongation of 55% or more.

7. The communication electric wire according to claim 1, being a coaxial electric wire comprising a metal shield layer on an outer periphery of the insulating layer,
wherein the magnetic sheath layer is located on an outer periphery of the metal shield layer.
